(19) United States
(12) Patent Application Publication
(10) Pub. No.: US 2026/0214788 A1
(43) Pub. Date: Jul. 23, 2026

(54) SUBSTRATE CARRIER AND MOTOR VEHICLE

(71) Applicant: HELLA GMBH & CO. KGAA, Lippstadt (DE)

(72) Inventor: Marcus Gattwinkel, Telgte (DE)

(21) Appl. No.: 19/451,297

(22) Filed: Jan. 16, 2026

(30) Foreign Application Priority Data
Jan. 20, 2025 (DE) 102025101846.4

(51) Int. Cl. H05K 1/02; H05K 1/05; H05K 1/181; H05K 3/00

(52) U.S. Cl. CPC H05K 1/0271; H05K 1/0203; H05K 1/05; H05K 1/181; H05K 3/0044; H05K 2201/066; H05K 2201/10015; H05K 2201/2081

(57) ABSTRACT

The present invention relates to a substrate carrier for mounting electronic components. The substrate carrier includes: a base body; at least one conductor track; and at least one electronic component. The electronic component is electrically conductively connected to the conductor track by means of at least one solder joint. The base body has at least one relief aperture, the relief aperture being configured to reduce thermal stretching of the solder joint by thermal stretching of the base body. The invention also relates to a motor vehicle including at least one substrate carrier.

### CROSS-REFERENCE TO RELATED APPLICATIONS

This application claims the benefit of German Patent Application 10-2025-101-846.4, filed Jan. 20, 2025, the disclosure of which is incorporated by reference in its entirety.

### FIELD OF THE INVENTION

The present invention relates to a substrate carrier for mounting electronic components, in particular for a motor vehicle. The invention also relates to a motor vehicle with at least one substrate carrier.

### BACKGROUND OF THE INVENTION

The printed circuit boards currently known to the public in the state of the art are made from a variety of different material combinations. Various cooling concepts are available for thermally sensitive electronic components and/or for electronic components in thermally demanding installation situations. A known cooling concept provides for at least partial heat dissipation via the printed circuit board itself. The printed circuit board is made of a material that is advantageously thermally conductive.

A disadvantage of the known solutions is that the electronic components and the printed circuit boards usually exhibit different thermal expansion behaviors, which results in stresses and/or cracks being generated in the electronic components and/or the connection points, in particular the solder joints of the electronic components, thereby reducing the reliability and/or service life of the devices.

It is therefore the object of the present invention to remedy or at least partially remedy the disadvantages described above in the prior art. In particular, it is the object of the invention to provide a substrate carrier which allows the mounting of electronic components and a reliable electrically conductive connection of the electronic components in a particularly easy manner. In particular, it is also the object of the invention to provide a motor vehicle with at least one substrate carrier.

### SUMMARY OF THE INVENTION

The above object is solved by the present invention. In particular, the above object is achieved by a substrate carrier and a motor vehicle as set forth herein.

Further advantages and details of the invention will become apparent from the the description and the drawings. Features that are described in connection with the substrate carrier according to the invention naturally also apply in connection with the motor vehicle according to the invention and vice versa, so that reference is or can always be made to the individual aspects of the invention with regard to the disclosure.

According to a first aspect of the invention, the object is achieved by a substrate carrier for mounting electronic components. The substrate carrier comprises a base body, at least one conductor track and at least one electronic component, wherein the at least one electronic component is electrically conductively connected to the at least one conductor track by means of at least one solder joint. The base body has at least one relief aperture, wherein the at least one relief aperture is configured to reduce thermal stretching of the at least one solder joint and/or the at least one electronic component by thermal stretching of the base body.

The substrate carrier is preferably understood to be a circuit board for mounting electronic components. The electronic components are preferably understood to be electronic and/or electrical components, in particular SMDs, which are arranged and/or attached to and/or at least in sections in the base body. The electronic components are preferably arranged on an upper side and/or a lower side of the base body. Preferably, the base body is configured in a plate-like shape and/or has a main extension plane. Preferably, the base body has a thickness orthogonal to the main extension plane.

The substrate carrier comprises at least one conductor track, preferably a plurality of conductor tracks for the electrically conductive connection of the electronic components. The electronic components are electrically connected to the conductive tracks with solder joints. The at least one conductor track is preferably designed around the at least one relief aperture and/or past the at least one relief aperture. The at least one conductor track is preferably configured at and/or on the base body. Preferably, the at least one conductor track is therefore not configured in the base body.

Preferably, the base body comprises several relief apertures. Particularly preferably, the base body comprises at least one relief aperture for each solder joint, wherein in particular at least two or more solder joints have at least one common relief aperture.

The core of the invention is preferably a reduction or even avoidance of thermal stretching of the solder joint and/or the electronic component by thermal stretching of the base body. This reduction or even avoidance of stress and/or stretching is made possible by the at least one relief aperture in the base body of the substrate carrier according to the invention. The at least one relief aperture reduces or avoids cracks in the solder joints over the service life of the substrate carrier.

By way of illustration and example, the at least one relief aperture enables at least partial decoupling or at least a reduction in the effective connection between the thermal stretching of the base body and the stretching of the solder joint and/or the thermal stretching of the electronic component. The at least one relief aperture is preferably a material recess and/or a volume from which material of the base body has been removed. The at least one relief aperture is preferably introduced before the substrate carrier mounted with the at least one electronic component in order to prevent damage to the at least one electronic component.

In the context of the invention, thermal stretching is preferably to be understood as both an expansion and a contraction of the base body, the electronic component and/or the solder joint. In other words, thermal stretching preferably also comprises thermal compression. Thermal stretching is preferably achieved by increasing or decreasing the temperature of the respective device, with the temperature being changed actively by the device itself or passively by another device and/or the environment.

Preferably, the geometry of the at least one relief aperture can be individually adapted to the type and/or the positions of the electronic components and/or the solder joints, for example on the basis of a CFD and/or FEM simulation.

A substrate carrier configured in this way is particularly advantageous, as the substrate carrier enables advantageous mounting of electronic components through the at least one relief aperture, wherein an electrically conductive connection of the at least one electronic component to the at least one conductor track by means of at least one solder joint is made possible in a particularly simple and reliable manner.

According to a preferred further development of the invention, for a substrate carrier it may be provided, that the substrate carrier is configured as an aluminum printed circuit board and/or as an IMS printed circuit board (insulated metal substrate), wherein in particular the base body is configured, a least in sections, and in particular completely, from aluminum. A configuration of the substrate carrier as an aluminum circuit board and/or IMS circuit board enables advantageous heat dissipation from the at least one electronic component via the substrate carrier itself. This advantageously saves space, material and costs for an additional cooling solution. The aluminum printed circuit board and/or IMS printed circuit board represent a cost-effective solution for dissipating heat from electronic components, for example for high-performance LED technology and electronics with high heat generation. The base body is configured of aluminum at least in sections, and in particular completely. The aluminum substrate carrier preferably has no internal layers for the conductor tracks. A substrate carrier configured in this way is particularly advantageous, as the substrate carrier, in particular due to the configuration of the base body, enables an advantageous mounting of electronic components, wherein an electrically conductive connection of the at least one electronic component to the at least one conductor track by means of at least one solder joint is made possible in a particularly simple and reliable manner.

According to a preferred further development of the invention, for a substrate carrier it may be provided that the at least one relief aperture is configured in the form of a continuous relief aperture from an upper side of the base body to an underside of the base body. The upper side and underside of the base body are preferably to be understood as being arranged opposite each other on the base body. The at least one relief aperture is preferably configured as a through-hole in the base body. Such a configuration of the at least one relief aperture enables cost-effective production and efficient reduction of the thermal stretching of the solder joint and/or the at least one electronic component by thermal stretching of the base body. The recess and/or removal of material of the base body for the at least one relief aperture preferably enables an advantageous deflection of thermal stretching of the base body and thus an advantageous reduction or even avoidance of thermal stretching of the solder joint and/or the at least one electronic component. The risk of cracks in the solder joints and/or damage to the electronic components is advantageously reduced by the configuration of the at least one relief aperture.

According to a preferred further development of the invention, for a substrate carrier it may be provided that the at least one relief aperture exhibits a main extension transverse to a main extension of the at least one electronic component and/or parallel to a main extension of the at least one solder joint.

The main extension of the respective device is to be understood as the largest geometric extension of the respective device. By way of illustration and example, for an electronic component that is significantly longer than it is wide and high, the length is the main extension.

A particularly advantageous reduction in thermal stretching of the solder joint and/or the at least one electronic component due to thermal stretching of the base body is made possible by an advantageous arrangement and/or alignment of the at least one relief aperture. Preferably, the main extension of the at least one relief aperture is arranged transversely to the main extension of the at least one electronic component. Alternatively or additionally, the main extension of the at least one relief aperture is arranged parallel to the main extension of the at least one solder joint. To put it clearly, the at least one relief aperture is preferably arranged parallel to an elongated solder joint and/or transversely to an elongated electronic component, so that a reduction in thermal stretching of the solder joint and/or the at least one electronic component is advantageously enabled by thermal stretching of the base body.

A substrate carrier configured in this way is particularly advantageous, as the substrate carrier, in particular due to the configuration of the at least one relief aperture, enables advantageous mounting of electronic components, wherein an electrically conductive connection of the at least one electronic component to the at least one conductor track by means of at least one solder joint is made possible in a particularly simple and reliable manner.

According to a preferred further development of the invention, for a substrate carrier it may be provided that the main extension of the at least one relief aperture has a factor of 1.0 to 2.0, in particular 1.2 to 1.5, in relation to the main extension of the at least one electronic component and/or in relation to the main extension of the at least one solder joint. Preferably, the at least one relief aperture is at least as wide as, or more preferably wider than, the at least one electronic component and/or the at least one solder joint. A relief aperture configured in this way enables an advantageous reduction or even avoidance of thermal stretching of the solder joint and/or the at least one electronic component due to thermal stretching of the base body. In particular in combination with the above-described alignment and/or arrangement of the at least one relief aperture in relation to the at least one electronic component and/or in relation to the at least one solder joint, the substrate carrier according to the invention enables advantageous operation and a reliable electrically conductive connection of the at least one electronic component to the at least one conductor track by means of at least one solder joint. A wider configuration and/or a higher factor of the main extension of the at least one relief aperture in relation to the main extension of the at least one electronic component and/or in relation to the main extension of the at least one solder joint enables improved sealing of the at least one electronic component and/or the at least one solder joint against thermal stretching of the base body.

According to a preferred further development of the invention, for a substrate carrier it may be provided that the at least one relief aperture is configured adjacent to and/or at least in sections surrounding the at least one solder joint, the at least one conductor track and/or the at least one electronic component. By way of illustration and example, the at least one relief aperture is arranged on at least one end face of an elongated electronic component and its solder joint. In the context of the invention, an arrangement of the at least one relief aperture adjacent to and/or at least in sections surrounding the at least one solder joint, the at least one conductor track and/or the at least one electronic component is preferably to be understood as a direct arrangement and/or as a directly adjacent arrangement of the at least one relief aperture to the at least one solder joint, the at least one conductor track and/or the at least one electronic component. Preferably, the at least one relief aperture is configured at least in sections along the at least one solder joint, the at least one conductor track and/or the at least one electronic component. Preferably, the at least one solder joint and the at least one relief aperture do not exhibit a spatial overlap, so that the solder joint is not disadvantageously influenced by the relief aperture and/or vice versa. A substrate carrier configured in this way is particularly advantageous, as the substrate carrier, in particular due to the arrangement of the at least one relief aperture, enables advantageous mounting of electronic components, wherein an electrically conductive connection of the at least one electronic component to the at least one conductor track by means of at least one solder joint is made possible in a particularly simple and reliable manner.

According to a preferred further development of the invention, for a substrate carrier it may be provided that the at least one relief aperture is configured at least in sections below the at least one electronic component. An arrangement of the at least one relief aperture at least in sections below the at least one electronic component advantageously enables a reduction and/or avoidance of thermal stretching of the at least one electronic component due to thermal stretching of the base body. In particular for electronic components that require less heat dissipation through the base body, this configuration and/or arrangement of the at least one relief aperture is an advantageous way of reducing thermal stretching of the at least one solder joint and/or the at least one electronic component by thermal stretching of the base body. A substrate carrier configured in this way is particularly advantageous, as the substrate carrier, in particular due to the arrangement and/or configuration of the at least one relief aperture at least in sections below the at least one electronic component, enables advantageous mounting of electronic components. Furthermore, the substrate carrier preferably enables an electrically conductive connection of the at least one electronic component to the at least one conductor track by means of at least one solder joint in a particularly simple and reliable manner.

According to a preferred further development of the invention, for a substrate carrier it may be provided that the base body has a thickness of at least 0.8 mm, in particular at least 1.1 mm, 1.3 mm or 1.5 mm. The base body is preferably configured in a plate-like shape. Preferably, the base body has a main extension plane, wherein the thickness is preferably to be understood as orthogonal to the main extension plane. A thickness of the base body of at least 0.8 mm, in particular at least 1.1 mm, 1.3 mm or 1.5 mm, advantageously enables a substrate carrier that is as flat as possible, even under thermal influence, while at the same time minimizing the use of material and costs. Furthermore, a base body configured in this way enables advantageous heat dissipation for the electronic components and/or the solder joints. The at least one relief aperture is preferably configured and/or inserted through the base body along the thickness.

According to a preferred further development of the invention, for a substrate carrier it be provided that the base body comprises at least one thermal conducting device, wherein the at least one thermal conducting device is configured to dissipate heat from the base body and/or from the at least one electronic component. The at least one thermal conducting device is preferably configured as an active and/or passive heat conducting device. The thermal conducting device is preferably integrated at least in sections in the base body and/or connected thereto in a thermally conductive manner. For example, the thermal conducting device is configured as a heat sink, cooling fins, a heat conducting tube and/or heat accumulator. A substrate carrier configured in this way enables particularly advantageous temperature control of the at least one electronic component and/or the at least one solder joint. The thermal conducting device preferably enables heat to be dissipated to reduce thermal stretching of the at least one solder joint and/or the at least one electronic component by thermal stretching of the base body. The thermal conducting device thus advantageously supports the at least one relief aperture and thus enables advantageous operation of the substrate carrier and/or the at least one electronic component.

According to a preferred further development of the invention, for a substrate carrier it may be provided that the base body has at least two relief apertures, with at least one heat transfer web being configured between the at least two relief apertures. A heat transfer web between two relief openings preferably enables a defined heat transfer in order to allow an advantageous equalization of the temperatures in the base body while at the same time reducing thermal stretching of the at least one solder joint and/or the at least one electronic component by thermal stretching of the base body. Furthermore, the at least one heat transfer web preferably enables an arrangement of at least one conductor track over the heat transfer web and thus an advantageous use of installation space. The at least one heat transfer web is preferably configured integrally with the base body and/or as an integral component of the base body. A substrate carrier configured in this way is particularly advantageous, as the substrate carrier enables advantageous mounting of electronic components by means of the at least one heat transfer web, wherein an electrically conductive connection of the at least one electronic component to the at least one conductor track by means of at least one solder joint is made possible in a particularly simple and reliable manner.

According to a preferred further development of the invention, for a substrate carrier it may be provided that the base body comprises at least one solder mask for the at least one solder joint, with in particular the at least one relief aperture being configured adjacent to and/or at least in sections surrounding the at least one solder mask. The solder mask preferably limits the maximum expansion of the solder joint. An arrangement of the at least one relief aperture adjacent to and/or at least sectionally surrounding the at least one solder mask advantageously enables the closest possible and/or most effective reduction of thermal stretching of the at least one solder joint and/or the at least one electronic component by thermal stretching of the base body. Furthermore, an arrangement of the at least one relief aperture adjacent to and/or at least partially surrounding the at least one solder mask avoids a spatial overlap of the at least one relief aperture with the at least one solder joint. A substrate carrier configured in this way is particularly advantageous, as the substrate carrier enables advantageous mounting of electronic components by means of the at least one solder mask, wherein an electrically conductive connection of the at least one electronic component to the at least one conductor track by means of at least one solder joint is made possible in a particularly simple and reliable manner.

According to a preferred further development of the invention, for a substrate carrier it may be provided that the at least one relief aperture has a right-angled or substantially right-angled configuration and/or an elongated hole configuration. In the context of the invention, the phrase “X or substantially X” is to be understood as a possible, minor deviation, for example due to manufacturing tolerances, material and/or process properties, without changing the underlying, intended function of the feature. Preferably, the at least one relief aperture has round corners, at least in sections, due to the manufacturing process. A right-angled configuration and/or an elongated hole configuration enables cost-effective manufacturing of the at least one relief aperture and at the same time a particularly efficient reduction in thermal stretching of the at least one solder joint and/or the at least one electronic component due to thermal stretching of the base body.

According to a preferred further development of the invention, for a substrate carrier it may be provided that the least one relief aperture is configured by punching, cutting, milling and/or laser cutting in the base body. Manufacturing of the at least one relief aperture using at least one of the above manufacturing steps enables cost-effective manufacturing of the at least one relief aperture and, at the same time, a particularly efficient reduction of thermal stretching of the at least one solder joint and/or the at least one electronic component by thermal stretching of the base body.

According to a preferred further development of the invention, for a substrate carrier it may be provided that the at least one electronic component is configured as a ceramic component, in particular as a ceramic capacitor. For a ceramic component, the substrate carrier according to the invention enables particularly advantageous and reliable operation. Ceramic components exhibit a low thermal expansion and therefore an increased risk of, for example, solder joint cracks due to thermal stretching of the base body. An arrangement of an electronic ceramic component on a substrate carrier according to the invention with at least one relief aperture advantageously enables a reduction in thermal stretching of the at least one solder joint and/or the at least one electronic component by thermal stretching of the base body.

According to a second aspect of the invention, the object is achieved by a motor vehicle with at least one substrate carrier according to the first aspect. The motor vehicle described offers all the advantages already described for the substrate carrier according to the first aspect of the invention.

### BRIEF DESCRIPTION OF THE DRAWINGS

A substrate carrier according to the invention and a motor vehicle are explained in more detail below with reference to drawings. The figures show schematically:

FIG. 1 is a top view of a substrate carrier with an electronic component and two relief openings;

FIG. 2 is a top view of a substrate carrier with a plurality of electronic components and five relief apertures; and

FIG. 3 is a top view of a motor vehicle with a substrate carrier.

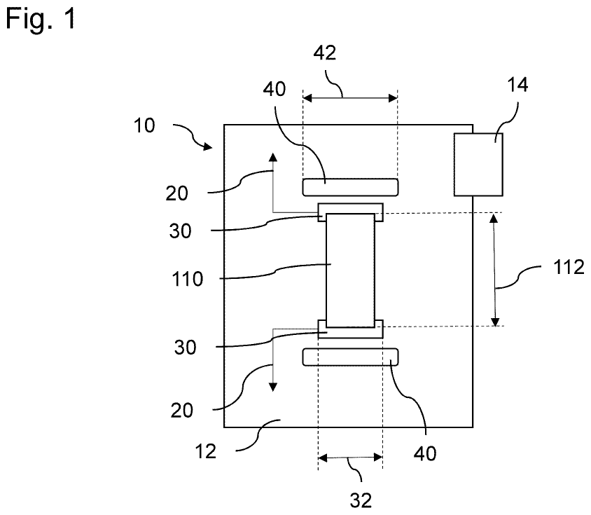

Elements with the same function and mode of operation are designated with the same reference signs in FIG. 1 to FIG. 3.

### DETAILED DESCRIPTION OF THE CURRENT EMBODIMENT

FIG. 1 shows a schematic top view of a substrate carrier 10 with an electronic component 110 and two relief apertures 40. The substrate carrier 10 comprises a base body 12, two conductor tracks 20 and an electronic component 110. The electronic component 110 is electrically connected to the two conductor tracks 20 by means of two solder joints 30. The base body 12 has the two relief apertures 40, wherein the two relief apertures 40 are configured to reduce thermal stretching of the two solder joints 30 and the electronic component 110 by thermal stretching of the base body 12. The substrate carrier 10 is configured as an aluminum circuit board, with sections of the base body 12 being configured of aluminum. The two relief apertures 40 are configured as continuous relief apertures 40 from an upper side of the base body 12 to an underside of the base body 12. The two relief apertures 40 each have a main extension 42 transverse to a main extension 112 of the electronic component 110 and parallel to a main extension 32 of the two solder joints 30. The base body 12 comprises a thermal conducting device 14, wherein the thermal conducting device 14 is configured to dissipate heat from the base body 12 and from the electronic component 110. The two relief apertures 40 have a right-angled configuration. The two relief apertures 40 are milled into the base body 12.

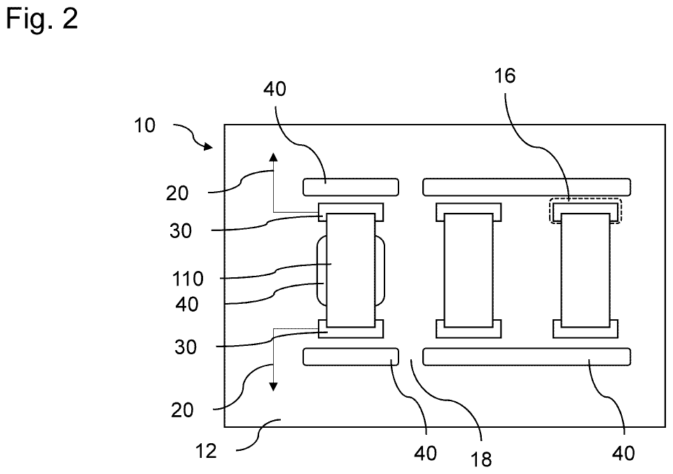

FIG. 2 shows a schematic top view of a substrate carrier 10 with a plurality of electronic components 110 and five relief apertures 40. The substrate carrier 10 comprises a base body 12, a plurality of conductor tracks 20, of which only two conductor tracks 20 are shown, and three electronic components 110. The electronic components 110 are each electrically conductively connected to the respective conductor tracks 20 by means of two solder joints 30. The base body 12 has the five relief apertures 40, wherein the five relief apertures 40 are configured to reduce thermal stretching of the two solder joints 30 and the electronic component 110 by thermal stretching of the base body 12. One of the relief apertures 40 is configured in sections below the left electronic component 110. The center and right electronic components 110 have two common relief apertures 40. The base body 12 has heat transfer webs 18 between the relief apertures 40. The base body 12 comprises a plurality of solder masks 16 for the solder joints 30, wherein only one is shown. The relief apertures 40 are configured adjacent to the solder masks 16.

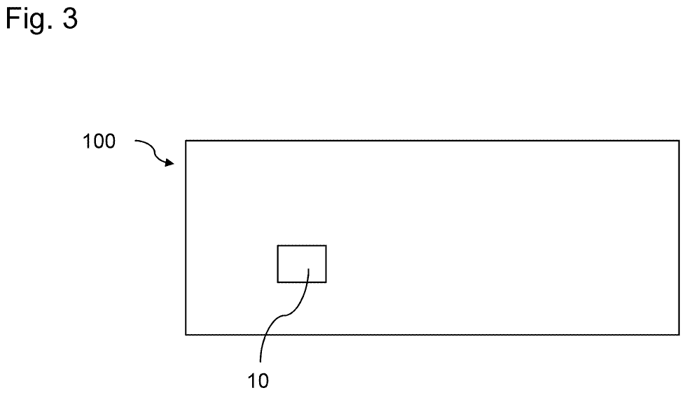

FIG. 3 shows a schematic top view of a motor vehicle 100 with a substrate carrier 10.

### LIST OF REFERENCE SIGNS

10 substrate carrier
12 base body
14 thermal conducting device
16 solder mask
18 heat transfer web
20 conductor track
30 solder joint
32 main extension of the solder joint
40 relief aperture
42 main extension of the relief aperture
100 motor vehicle
110 electronic component
112 main extension of the electronic component

The above description is that of a current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A substrate carrier for mounting electronic components, the substrate carrier comprising:
a base body;
at least one conductor track; and
at least one electronic component, the at least one electronic component being electrically conductively connected to the at least one conductor track via at least one solder joint;
wherein the base body has at least one relief aperture, the at least one relief aperture being configured to reduce thermal stretching of the at least one solder joint or the last one electronic component by thermal stretching of the base body.

2. The substrate carrier of claim 1, wherein the base body comprises an aluminum printed circuit board.

3. The substrate carrier of claim 1, wherein the at least one relief aperture extends from an upper side of the base body to an underside of the base body.

4. The substrate carrier of claim 1, wherein the at least one relief aperture has a main extension that is transverse to a main extension of the at least one electronic component or parallel to a main extension of the least one solder joint.

5. The substrate carrier of claim 4, wherein the main extension of the at least one relief aperture has a factor of 1.0 to 2.0 in relation to the main extension of the at least one solder joint.

6. The substrate carrier of claim 1, wherein the at least one aperture is adjacent to the at least one solder joint, the at least one conductor track, or the at least one electronic component.

7. The substrate carrier of claim 1, wherein the at least one aperture is configured in sections below the at least one electronic component.

8. The substrate carrier of claim 1, wherein the base body has a thickness of at least 0.8 mm.

9. The substrate carrier of claim 1, wherein the base body comprises at least one heat sink to dissipate heat from the electronic component.

10. The substrate carrier of claim 1, wherein the at least one relief aperture includes two relief apertures that are separated by a heat transfer web.

11. The substrate carrier of claim 1, wherein the base body comprises at least one solder mask for the at least one solder joint.

12. The substrate carrier of claim 1, wherein the at least one relief aperture has a rectangular configuration.

13. The substrate carrier of claim 1, wherein the at least one relief opening is formed by punching, cutting, milling, or laser cutting the base body.

14. The substrate carrier of claim 1, wherein the at least one electronic component comprises a ceramic capacitor.

15. A motor vehicle comprising the substrate carrier of claim 1.
